(19) United States
(12) Patent Application Publication
(10) Pub. No.: US 2016/0284595 A1
(43) Pub. Date: Sep. 29, 2016

(54) SELECTIVE ANALOG AND RADIO FREQUENCY PERFORMANCE MODIFICATION

(71) Applicant: QUALCOMM Incorporated, San Diego, CA (US)

(72) Inventors: Chunqi GENG, San Diego, CA (US); Choh Fei YEAP, San Diego, CA (US); Stanley Seungchul SONG, San Diego, CA (US)

(21) Appl. No.: 14/670,314

(22) Filed: Mar. 26, 2015

(51) Int. Cl. H01L 21/8234; H01L 27/088

(52) U.S. Cl. CPC H01L 21/823412; H01L 27/088; H01L 21/823418

(57) ABSTRACT

A semiconductor chip includes a circuit block. The circuit block includes a first transistor(s) having an enhanced first performance characteristic different from a second performance characteristic of a second transistor(s) of the circuit block. The circuit block also includes a marker layer to identify the first transistor(s).

### BACKGROUND

1. Field

Aspects of the present disclosure relate to semiconductor devices, and more particularly to selective enhancement or modification of transistors.

2. Background

The process flow for semiconductor fabrication of integrated circuits (ICs) may include front-end-of-line (FEOL), middle-of-line (MOL), and back-end-of-line (BEOL) processes. The front-end-of-line processes may include wafer preparation, isolation, well formation, gate patterning, spacer, extension and source/drain implantation, silicide formation, and dual stress liner formation. The middle-of-line process may include gate contact formation. Middle-of-line layers may include, but are not limited to, middle-of-line contacts, vias or other layers within close proximity to the semiconductor device transistors or other like active devices. The back-end-of-line processes may include a series of wafer processing steps for interconnecting the semiconductor devices created during the front-end-of-line and middle-of-line processes. Successful fabrication of modern semiconductor chip products involves an interplay between the materials and the processes employed.

Mobile RF (radio frequency) chip (e.g., transceiver) designs may be fabricated using an interposer. An interposer is a die-mounting technology in which the interposer serves as a base upon which the mobile RF chip is mounted. An interposer is an example of a fan out wafer level package structure. The interposer may include wiring layers of conductive traces and conductive vias for routing electrical connections between the mobile RF chip (e.g., a transceiver) and a system board. The interposer may include a redistribution layer (RDL) that provides a connection pattern of bond pads on the active surface of the mobile RF transceiver to a redistributed connection pattern that is more suitable for connection to the system board.

The design of analog and radio frequency integrated circuit chips, including mobile RF chips as transceivers, has migrated to sub-micron process nodes due to cost and power consumption considerations. Unfortunately, a reduced supply voltage and relatively higher threshold voltage (Vₜₕ) from the foundry default device options may result in decreased headroom and significantly affect the chip's performance. Added circuit function and design complexity (e.g., carrier aggregation support), and other device analog/RF performance considerations (e.g., mismatch, noise, etc.) may present further design challenges. Due to model and simulation tool limitations or changes in chip specifications after design, or in the case that performance does not meet the specifications, redesign of the chip may be desired. Unfortunately, chip redesign is very expensive. Furthermore, redesigning a chip may greatly impact the production cycle, in some case extending the production cycle by several months.

### SUMMARY

A semiconductor chip includes a circuit block. The circuit block includes a first transistor(s) having an enhanced first performance characteristic different from a second performance characteristic of a second transistor(s) of the circuit block. The circuit block also includes a marker layer to identify the first transistor(s).

A method for performance enhancement of an integrated circuit (IC) chip includes selecting a circuit block(s) of the IC chip according to a predetermined performance criteria. The method also includes marking at least one first transistor within the selected circuit block(s). The first transistor may be identified according to the predetermined performance criteria. The method further includes adjusting performance of the at least one first transistor.

A semiconductor chip includes a circuit block. The circuit block includes a first transistor(s) having an enhanced first performance characteristic different from a second performance characteristic of a second transistor(s) of the circuit block. The semiconductor chip also includes means for separating the first transistor(s) from the second transistor(s).

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer in an aspect of the present disclosure.

FIG. 2 illustrates a cross-sectional view of a die in accordance with an aspect of the present disclosure.

FIG. 3 illustrates a cross-sectional view of a metal-oxide-semiconductor field-effect transistor (MOSFET) device in an aspect of the present disclosure.

FIG. 4 illustrates a top view of an integrated circuit chip in accordance with an aspect of the present disclosure.

FIG. 5 is a process flow diagram illustrating a method for fabricating a semiconductor device according to an aspect of the present disclosure.

FIG. 6 is a block diagram showing an exemplary wireless communication system in which a configuration of the disclosure may be advantageously employed.

FIG. 7 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Mobile RF (radio frequency) chip (e.g., transceiver) designs have migrated to a deep sub-micron process node due to cost and power consumption considerations. The design of such mobile RF transceivers, however, may be limited by the current foundry default device options. In particular, a reduced supply voltage and relatively higher threshold voltage (Vₜₕ) specified by the foundry default device options may result in decreased headroom (e.g., at least a several hundred millivolt drop). Unfortunately, a several hundred millivolt drop in device headroom detrimentally affects chip performance.

Added circuit function and design complexity (e.g., carrier aggregation support), and other device analog/RF performance considerations (e.g., mismatch, noise, etc.) may present further design challenges. Due to model and simulation tool limitations or changes in chip specifications after design, or in the case that performance does not meet the chip specifications, redesign of the chip may be desired. Unfortunately, chip redesign is very expensive. Furthermore, redesigning a chip may greatly impact the production cycle, in some case extending the production cycle by several months.

In one aspect of the disclosure, critical transistors in certain key circuit blocks may be identified. In some aspects, the key circuit blocks include transceivers, regulators (e.g., low drop out (LDO) regulators) or other circuit blocks that have high headroom margin and/or other strict device performance specifications. The circuit block performance may be verified, for example, by applying a beyond 3-sigma process corner condition on selected transistors. In a beyond 3-sigma process corner, selected transistors may be tested to determine if direct current (DC), analog and RF performance (e.g., threshold voltage, drain current, transconductance (Gm), mismatch, noise, etc.) are within three standard deviations of a mean or “typical” performance using simulation data. A graphic data system (GDS) marker layer may be drawn to cover the selected transistors in the critical circuit block. Having identified selected transistors, a performance boost may be applied to the selected transistors rather than the entire chip (or the entire function block).

Various aspects of the disclosure are directed to techniques for fabrication of a semiconductor device and more particularly to increasing performance of selected transistors of a semiconductor chip to accommodate circuit specification change without redesigning the chip or sacrificing power. It will be understood that the term “layer” includes film and is not to be construed as indicating a vertical or horizontal thickness unless otherwise stated. As described herein, the term “substrate” or may refer to a substrate of a diced wafer or may refer to the substrate of a wafer that is not diced. Similarly, the terms chip and die may be used interchangeably unless such interchanging would tax credulity.

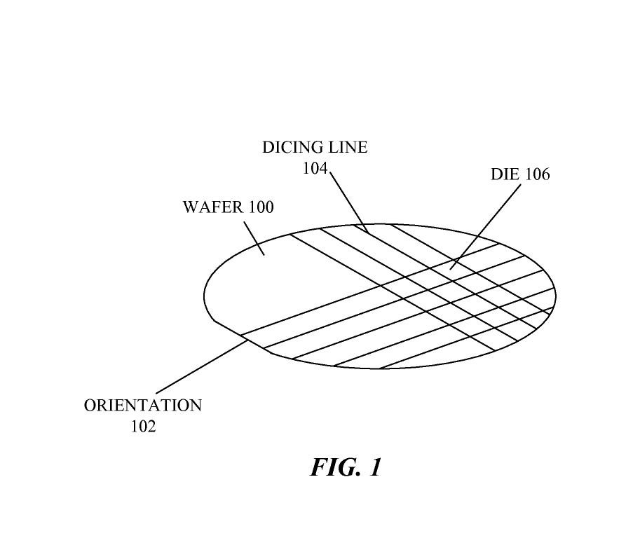

FIG. 1 illustrates a perspective view of a semiconductor wafer in an aspect of the present disclosure. A wafer 100 may be a semiconductor wafer, or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be a compound material, such as gallium arsenide (GaAs) or gallium nitride (GaN), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants, and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, different types of electronic devices may be formed in or on the wafer 100.

The wafer 100 has an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller Indices for the planes of the crystal lattice in the wafer 100.

The Miller Indices form a notation system of the crystallographic planes in crystal lattices. The lattice planes may be indicated by three integers h, k, and t, which are the Miller indices for a plane (hkl) in the crystal. Each index denotes a plane orthogonal to a direction (h, k, l) in the basis of the reciprocal lattice vectors. The integers are usually written in lowest terms (e.g., their greatest common divisor should be 1). Miller index 100 represents a plane orthogonal to direction h; index 010 represents a plane orthogonal to direction k, and index 001 represents a plane orthogonal to l. For some crystals, negative numbers are used (written as a bar over the index number) and for some crystals, such as gallium nitride, more than three numbers may be employed to adequately describe the different crystallographic planes.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

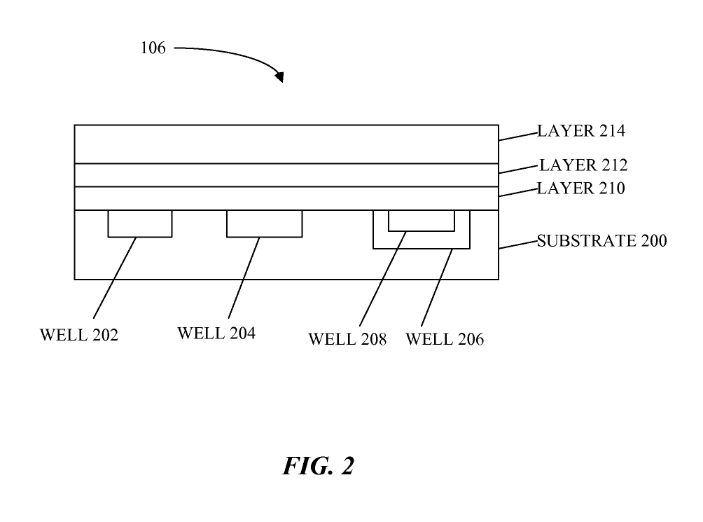

FIG. 2 illustrates a cross-sectional view of a die 106 in accordance with an aspect of the present disclosure. In the die 106, there may be a substrate 200, which may be a semiconductor material and/or may act as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within a substrate 200 (e.g., a semiconductor substrate), there may be wells 202 and 204, which may be the source and/or drain of a field-effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have a well 206 and a well 208. The well 208 may be completely within the well 206, and, in some cases, may form a bipolar junction transistor (BJT). The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, and other methods may create the structures and devices of the present disclosure.

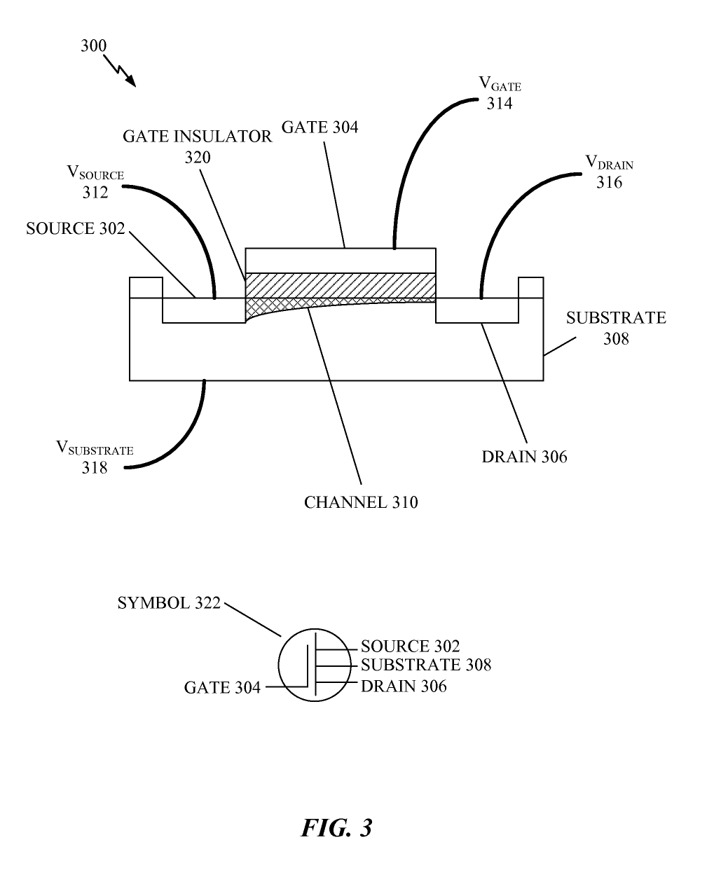

FIG. 3 illustrates a cross-sectional view of a metal-oxide-semiconductor field-effect transistor (MOSFET) device 300 in an aspect of the present disclosure. The MOSFET device 300 may have four input terminals. The four inputs are a source 302, a gate 304, a drain 306, and a substrate 308. The source 302 and the drain 306 may be fabricated as the wells 202 and 204 in the substrate 308, or may be fabricated as areas above the substrate 308, or as part of other layers on the die 106. Such other structures may be a fin or other structure that protrudes from a surface of the substrate 308. Further, the substrate 308 may be the substrate 200 on the die 106, but substrate 308 may also be one or more of the layers (e.g., 210-214) that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in the channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314 or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. The gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide, or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For p-type MOSFETs (using holes as charge carriers in the channel 310), an arrow is applied to the substrate 308 terminal in the symbol 322 pointing toward the gate 304 terminal.

The gate 304 may also be made of different materials. In some designs, the gate 304 is made from polycrystalline silicon, also referred to as polysilicon or poly, which is a conductive form of silicon. Although referred to as “poly” or “polysilicon” herein, metals, alloys, or other electrically conductive materials are contemplated as appropriate materials for the gate 304 as described in the present disclosure.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal Although referred to as “metal,” polycrystalline materials, alloys, or other electrically conductive materials are contemplated as appropriate materials for the gate 304 as described in the present disclosure.

To interconnect to the MOSFET device 300, or to interconnect to other devices in the die 106 (e.g., semiconductor), interconnect traces or layers are used. These interconnect traces may be in one or more of layers (e.g., 210-214), or may be in other layers of the die 106.

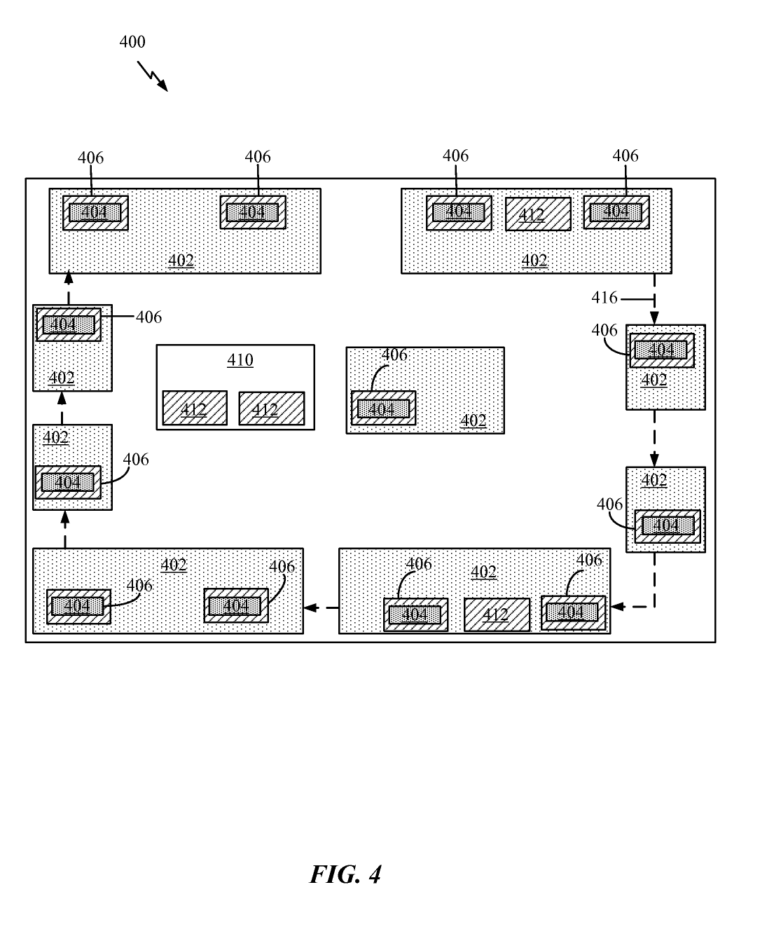

FIG. 4 is a block diagram illustrating an exemplary integrated circuit (IC) chip according to an aspect of the present disclosure. Representatively, the IC chip 400 may be configured as an analog or radio frequency (RF) IC chip (e.g., a transceiver). The design of the IC chip 400 may be limited by current foundry default device options. Unfortunately, the reduced supply voltage and the relatively higher threshold voltage (Vₜₕ) specified by the current foundry default device options may result in decreased headroom (e.g., at least a several hundred millivolt drop) available to, for example, a mobile RF chip. In particular, a several hundred millivolt drop in device headroom may detrimentally affect the performance of the mobile RF chip. In addition, added circuit function and design complexity (e.g., carrier aggregation support), and other device analog/RF performance considerations (e.g., mismatch, noise, etc.) may present further design challenges.

The IC chip 400 may include multiple circuit blocks (e.g., 402, 410), each of which may include one or more transistors (e.g., 404, 412) configured, for example, as shown in FIG. 3. The IC chip 400 may be subjected to validation testing to verify that the IC chip 400 meet certain predetermined design specifications. Due to model and simulation tool limitations or changes in chip specifications after design, or in the case that performance does not meet the chip specifications, redesign of the chip may be desired. In one aspect of the present disclosure, when the IC chip 400 fails to meet the predetermined and/or revised design specifications, a performance enhancement of the IC chip 400 is performed rather than a redesign of the IC chip 400.

In this aspect of the disclosure, the performance enhancement of the IC chip 400 begins by identifying the key circuit blocks 402 (e.g., a voltage regulator) and the non-key circuit blocks 410 of the IC chip 400. The critical transistors 404 in the key circuit blocks 402 are then identified. The critical transistors 404 in the key circuit blocks 402 may be transistors having the highest specification of headroom (and/or other device analog/RF performance) margin. These transistors play a significant role in determining the headroom (and/or other analog/RF key characteristics) and overall chip analog and RF performance.

For example, the critical transistors 404 within the key circuit blocks 402 are identified by subjecting the transistors (e.g., 404) of key circuit blocks 402 to a tuning process, or other like degree process tuning (e.g., a 3-sigma). For example, a 3-sigma corner simulation may be used to verify that certain IC design and performance metrics (e.g., threshold voltage, drain current, transconductance, noise and other metrics) are satisfied. In one aspect of the disclosure, the critical transistors 404 enhance circuit functionality because they include characteristics (e.g., DC (direct current), analog and RF performance (e.g., Vt, drain current, Gm (transconductance), mismatch, noise, etc.) that are different from typical conditions.

In this aspect of the disclosure, chip redesign is avoided when performance of the IC chip 400 does not meet the original and/or revised chip specifications. Rather than redesign the chip, in this aspect of the present disclosure, the key circuit blocks 402 that do not satisfy analog or RF performance metrics or other design specifications may be identified and/or targeted for performance adjustment. In some aspects, the key circuit blocks 402 may be arranged along a critical path such as a path 416 along the outer periphery of the IC chip 400 or another path along the IC chip 400. In some aspects, the critical path may be determined based on validation processing or other metrics.

Within these key circuit blocks 402, the critical transistors 404 may be identified. The critical transistors 404 may include key transistors that show dominant effects on circuit performance or have high specifications for headroom and analog or RF performance, for instance. A marker layer 406 may be applied to the critical transistors 404 to indicate the transistors for which performance adjustment is desired. Notably, the performance adjustment may be applied to only the critical transistors 404, as identified by a marker layer 406, which may be a subset of the transistors rather than all transistors of the IC chip, such as the non-critical transistors 412.

In some aspects, the marker layer 406 may be a graphic data system (GDS) marker layer, a halo implant marker layer and/or a lightly-doped drain (LDD) implant marker layer. Thereafter, during a semiconductor process, a special implant may be applied to the marked transistors to reduce threshold voltage, improve headroom or otherwise adjust the transistor and/or overall chip performance. In this configuration, a circuit block (e.g., 402) including at least one first transistor (e.g., 404) having an enhanced first performance characteristic different from a second performance characteristic of at least one second transistor (e.g., 412) of the circuit block. The enhanced first performance characteristic and the second performance characteristic may include a dopant profile and/or a gate oxide thickness. For example, the dopant profile and/or the gate oxide thickness of the critical transistors 404 is changed from the dopant profile and/or the gate oxide thickness of the non-critical transistors 412.

In some aspects, the performance characteristic may be enhanced by creating implant masks to separate the critical transistors 404 inside the marker layer 406 from the non-critical transistors 412 outside of the marker layer 406. That is, the transistors inside the marker layer 406 include only the critical transistors 404, and the transistors outside of the marker layer 406 include only the non-critical transistors 412. A different dopant profile may be applied to the transistors based on whether the transistor is inside or outside of the marker layer 406. The different dopant profiles may include a lightly-doped drain (LDD) implant, a halo implant, or a well implant. For example, a lower implant dose may be used on transistors inside the marker layer 406 than outside the marker layer 406. This approach may be used for both n-channel devices and p-channel devices. As such, the selected n-channel and p-channel transistors may be adjusted to have a lower threshold voltage Vₜₕ so that the headroom and corresponding circuit performance may be improved. In this way, the performance adjustment may be selectively applied only to the critical transistors 404 without adjusting the non-critical transistors 412.

In some aspects, the performance may be adjusted by applying a Graphic Data System (GDS) marker layer to the critical transistors 404 to generate a mask for thinner gate oxide layers of the critical transistors 404. As such the gate oxide thickness for the critical transistors 404 may be different than the gate oxide thickness of the non-critical transistors 412. An implant may then be used on transistors inside the marker layer such that the threshold voltage (Vₜₕ) is performance adjusted to a desired level (e.g., according to design specifications). This approach may be used for both n-channel devices and p-channel devices so that the selected n-channel and p-channel devices (i.e., transistors) may be adjusted to have a lower threshold voltage Vₜₕ. As a result, headroom and circuit performance may be improved. Accordingly, the performance adjustment of reducing the gate oxide thickness may be selectively applied only to the critical transistors 404 without adjusting the non-critical transistors 412.

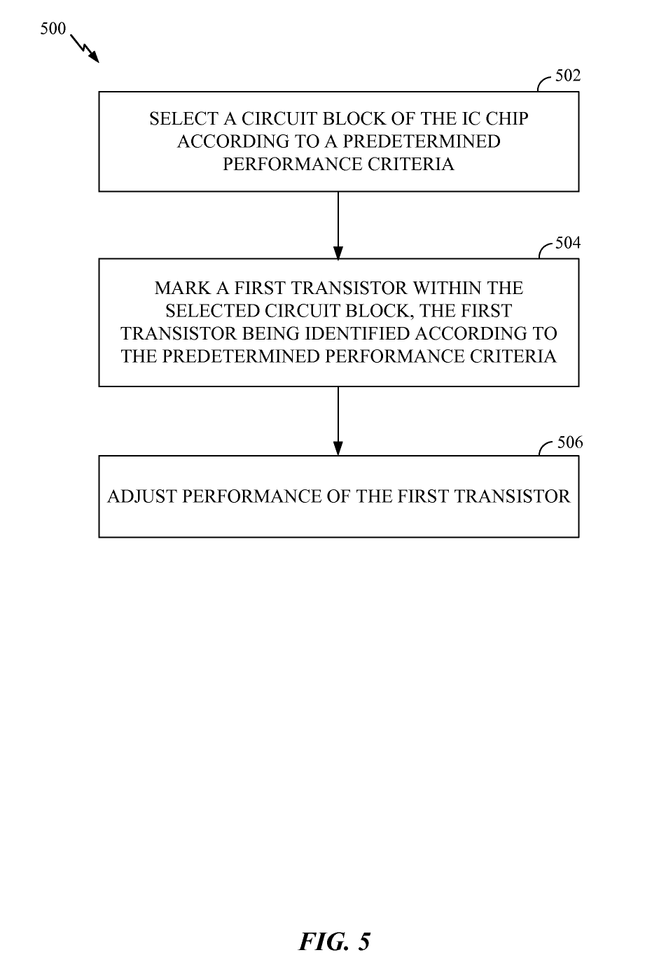

FIG. 5 is a flow diagram illustrating a method 500 for performance enhancement of an integrated circuit (IC) chip according to one aspect of the disclosure. At block 502, a circuit block of the IC chip is selected according to a predetermined performance criteria. The IC chip may comprise an analog IC or a radio frequency (RF) IC, for example. In some aspects, selecting the circuit block may comprise identifying circuit blocks within a critical path. The critical path may be a path along the outer periphery of the IC or any other path of the IC. Further, the critical path may be determined based on simulation. At block 504, a first transistor within the selected circuit block is marked. At block 506, performance of the first transistor is adjusted. The other transistors of the circuit block that are not selected are not adjusted.

TABLE 1
Performance Comparison
Device Performance Gain Compared to Foundry Default Option

| Device | Supply Voltage | | | Headroom | |
|---|---|---|---|---|---|
| Option | (Vdd) | | Vt_gm | (Vdd-Vt) | Comment |
| Method A | 1.05 | | ~150 mV | ~150 mV | Significant Headroom |
| | | | lower | higher | Improvement. |
| Method B | Option 1 | 1.05 | ~150 mV | ~150 mV | Same headroom |
| | | | lower | higher | improvement as method A |
| | | | | | with lower leakage current. |
| | Option 2 | 0.95 | ~250 mV | ~150 mV | Same headroom |
| | | | lower | higher | improvement as Option 1 |
| | | | | | with lower power |
| | | | | | consumption |
| | Option 3 | 1.05 | ~250 mV | ~250 mV | More headroom |
| | | | lower | higher | improvement compared |
| | | | | | with Options 1 and 2. |

Table 1 illustrates a circuit performance comparison. In this example, a headroom performance comparison within a twenty-eight (28) nanometer process node is described. In some aspects, adjusting performance of the one more first transistors under Method A may include doping the first transistors with a first doping implant profile different from a second doping implant profile of at least one second transistor within the circuit block. For example, a lower implant dose may be used on transistors inside the marker layer than outside the marker layer. This approach may be used for both n-channel devices and p-channel devices. As such, the selected n-channel and p-channel devices (i.e., transistors) may be adjusted to have a lower threshold voltage Vₜₕ so that the headroom and corresponding circuit performance may be improved.

As shown in Table 1, Method A yields a threshold voltage Vₜ_{_}_{gm} that is one hundred-fifty (150) millivolts lower, thereby providing a hundred-fifty (150) millivolts headroom increase. In some aspects, adjusting performance of the one more first transistors under Method B may also include reducing a gate oxide thickness of the at least one first transistor with the circuit block such that the threshold voltage (Vₜₕ) may be adjusted to a desired level (e.g., according to design specifications). As shown in Table 1, Method B, under Option 1, yields a similar threshold voltage Vₜ_{_}_{gm} improvement and a headroom improvement to Method A, but the leakage current is reduced under Option 1.

As further illustrated in Table 1, under Option 2, the supply voltage is reduced (e.g., 0.95 V) according to the gate oxide thickness reduction. Accordingly, Method B, under Option 2, yields a reduced threshold voltage Vₜ_{_}_{gm} (e.g., 250 mV) and a similar headroom improvement to Method A. The reduced supply voltage (Vdd), however, provides Option 2 with less power consumption. Under Option 3, both Method A and Method B, Option 1, are performed by using both a different dopant profile and a gate oxide thickness reduction. As shown in Table 1, Method B, under Option 2, yields a headroom improvement to both Method A and Method B, under Option 1 and Option 2.

As noted, the current foundry default device options specify a reduced supply voltage and a relatively higher threshold voltage (Vₜₕ). As a result, a mobile RF chip fabricated using the current foundry default device options experiences a decrease in available headroom (e.g., at least a several hundred millivolt drop) that. Unfortunately, a several hundred millivolt drop in device headroom may detrimentally affect the performance of the mobile RF chip.

Moreover, added circuit function and design complexity and other device analog/RF performance considerations (e.g., mismatch, noise, etc.) may present further design challenges. Due to model and simulation tool limitations or changes in chip specifications after design, or in the case that performance does not meet the chip specifications, redesign of the chip may be desired.

In some aspects, chip redesign is avoided when performance of the chip does not meet the original and/or revised chip specifications. Rather than redesign the chip, in this aspect of the present disclosure certain critical circuit blocks that do not satisfy analog or RF performance metrics or other design specifications may be identified and/or targeted for performance adjustment. In some aspects, the critical circuit blocks may be arranged along a critical path (e.g., along the outer periphery of an IC chip or another path along the IC chip). In some aspects, the critical path may be determined based on validation processing or other metrics.

Within these critical circuit blocks, one or more transistors may be identified. These transistors may include key transistors that show dominant effects on circuit performance or have high specifications on headroom and analog or RF performance, for instance. An implant marker layer may be applied to the identified transistors to indicate the transistors for which performance adjustment is desired. Notably, the performance adjustment may be applied to a subset of the transistors rather than all transistors of the IC chip including less critical transistors. That is, boosting performance of only selected components of the selected circuit block, including the key transistors, improves overall performance of the IC chip

According to an aspect of the present disclosure, a semiconductor chip is described. In one configuration, the semiconductor chip includes a circuit block including a first transistor having an enhanced first performance characteristic different from a second performance characteristic of a second transistor of the circuit block. The semiconductor chip includes means for separating the first transistor from the second transistor. The separating means may be the marker layer 406. In another aspect, the aforementioned means may be any module or any apparatus or material configured to perform the functions recited by the aforementioned means.

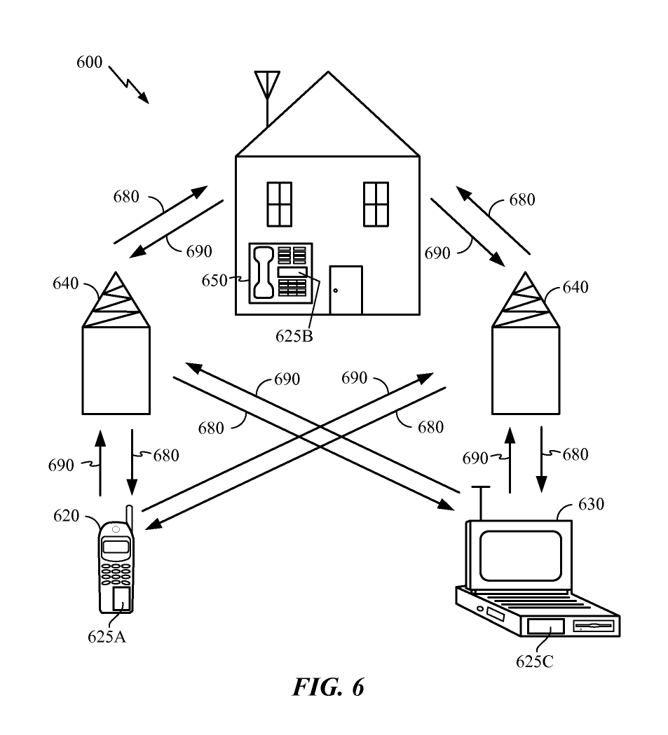

FIG. 6 is a block diagram showing an exemplary wireless communication system 600 in which an aspect of the disclosure may be advantageously employed. For purposes of illustration, FIG. 6 shows three remote units 620, 630, and 650 and two base stations 640. It will be recognized that wireless communication systems may have many more remote units and base stations. Remote units 620, 630, and 650 include IC devices 625A, 625C, and 625B which may comprise the disclosed semiconductor chips and integrated circuit devices. It will be recognized that other devices may also include the semiconductor chips and integrated circuit devices, such as the base stations, switching devices, and network equipment. FIG. 6 shows forward link signals 680 from the base station 640 to the remote units 620, 630, and 650 and reverse link signals 690 from the remote units 620, 630, and 650 to base stations 640.

In FIG. 6, remote unit 620 is shown as a mobile telephone, remote unit 630 is shown as a portable computer, and remote unit 650 is shown as a fixed location remote unit in a wireless local loop system. For example, the remote units 620, 630, and 650 may be a mobile phone, a hand-held personal communication system (PCS) unit, a portable data unit such as a personal data assistant, a GPS enabled device, a navigation device, a set top box, a music player, a video player, an entertainment unit, a fixed location data unit such as a meter reading equipment, or other devices that store or retrieve data or computer instructions, or combinations thereof. Although FIG. 6 illustrates remote units according to the aspects of the disclosure, the disclosure is not limited to these exemplary illustrated units. Aspects of the disclosure may be suitably employed in many devices, which include the disclosed semiconductor chips and integrated circuit devices.

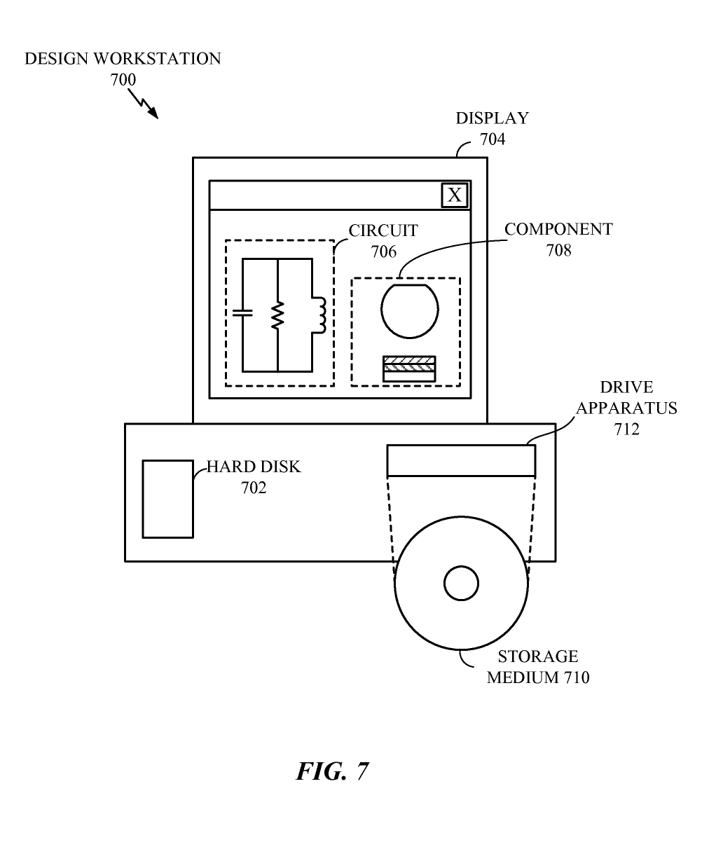

FIG. 7 is a block diagram illustrating a design workstation used for circuit, layout, and logic design of a semiconductor component, such as the IC devices disclosed above. A design workstation 700 includes a hard disk 702 containing operating system software, support files, and design software such as Cadence or OrCAD. The design workstation 700 also includes a display 704 to facilitate design of a circuit 706 or a semiconductor component 708 such as a semiconductor device. A storage medium 710 is provided for tangibly storing the design of the circuit 706 or the semiconductor component 708. The design of the circuit 706 or the semiconductor component 708 may be stored on the storage medium 710 in a file format such as GDSII or GERBER. The storage medium 710 may be a CD-ROM, DVD, hard disk, flash memory, or other appropriate device. Furthermore, the design workstation 700 includes a drive apparatus 712 for accepting input from or writing output to the storage medium 710.

Data recorded on the storage medium 710 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 710 facilitates the design of the circuit 706 or the semiconductor component 708 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD) and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification and in Appendix A. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above and in Appendix A generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD) and Blu-ray disc where disks usually reproduce data magnetically, while discs reproduce data optically with lasers. Combinations of the above should also be included within the scope of computer-readable media.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “a step for.”

What is claimed is:

1. A semiconductor chip, comprising:
a circuit block including at least one first transistor having an enhanced first performance characteristic different from a second performance characteristic of at least one second transistor of the circuit block; and
a marker layer to identify the at least one first transistor.

2. The semiconductor chip of claim 1, in which the first enhanced performance characteristic comprises a dopant profile and/or a gate oxide thickness.

3. The semiconductor chip of claim 2, in which the dopant profile comprises a lightly-doped drain (LDD) implant, a halo implant, or a well implant.

4. The semiconductor chip of claim 1, in which performance of only selected components of the semiconductor chip, including the first transistor, is boosted, thereby improving overall performance of the semiconductor chip.

5. The semiconductor chip of claim 1, in which the semiconductor chip is integrated into a mobile phone, a set top box, a music player, a video player, an entertainment unit, a navigation device, a computer, a hand-held personal communication system (PCS) unit, a portable data unit, and/or a fixed location data unit.

6. A method for performance enhancement of an integrated circuit (IC) chip, comprising:
selecting at least one circuit block of the IC chip according to a predetermined performance criteria;
marking at least one first transistor within the selected circuit block, the first transistor being identified according to the predetermined performance criteria; and
adjusting performance of the at least one first transistor.

7. The method of claim 6 in which adjusting performance comprises doping the first transistor with a first doping implant profile different from a second doping implant profile of at least one second transistor within the at least one circuit block.

8. The method of claim 6, in which adjusting performance comprises reducing a gate oxide thickness of the at least one first transistor with the at least one circuit block.

9. The method of claim 6, in which the IC chip comprises an analog IC or a radio frequency (RF) IC.

10. The method of claim 6, in which the selecting comprises identifying circuit blocks within a critical path.

11. The method of claim 6, further comprising boosting performance of only selected components of the selected circuit block, including the first transistor, thereby improving overall performance of the IC chip.

12. The method of claim 6, in which the IC chip is integrated into a mobile phone, a set top box, a music player, a video player, an entertainment unit, a navigation device, a computer, a hand-held personal communication systems (PCS) unit, a portable data unit, and/or a fixed location data unit.

13. A semiconductor chip, comprising:
a circuit block including at least one first transistor having an enhanced first performance characteristic different from a second performance characteristic of at least one second transistor of the circuit block; and
means for separating the at least one first transistor from the at least one second transistor.

14. The semiconductor chip of claim 13, in which the first enhanced performance characteristic comprise a dopant profile and/or a gate oxide thickness.

15. The semiconductor chip of claim 14, in which the dopant profile comprises a lightly-doped drain (LDD) implant, a halo implant, or a well implant.

16. The semiconductor chip of claim 13, in which performance of only selected components of the semiconductor chip, including the first transistor, is boosted, thereby improving overall performance of the semiconductor chip.

17. The semiconductor chip of claim 13, in which the semiconductor chip is integrated into a mobile phone, a set top box, a music player, a video player, an entertainment unit, a navigation device, a computer, a hand-held personal communication system (PCS) unit, a portable data unit, and/or a fixed location data unit.

18. A method for performance enhancement of an integrated circuit (IC) chip, comprising:
a step for selecting at least one circuit block of the IC chip according to a predetermined performance criteria;
a step for marking at least one first transistor within the selected circuit block, the first transistor being identified according to the predetermined performance criteria; and
a step for adjusting performance of the at least one first transistor.

19. The method of claim 18 in which the step for adjusting performance comprises a step for doping the first transistor with a first doping implant profile different from a second doping implant profile of at least one second transistor within the at least one circuit block.

20. The method of claim 18, in which the step for adjusting performance comprises a step for reducing a gate oxide thickness of the at least one first transistor with the at least one circuit block.

21. The method of claim 18, in which the IC chip comprises an analog IC or a radio frequency (RF) IC.

22. The method of claim 18, in which the step for selecting comprises a step for identifying circuit blocks within a critical path.

23. The method of claim 18, further comprising a step for boosting performance of only selected components of the selected circuit block, including the first transistor, thereby improving overall performance of the IC chip.

24. The method of claim 18, further comprising a step for integrating the IC chip into a mobile phone, a set top box, a music player, a video player, an entertainment unit, a navigation device, a computer, a hand-held personal communication systems (PCS) unit, a portable data unit, and/or a fixed location data unit.
